(19) United States
(12) Patent Application Publication
(10) Pub. No.: US 2018/0301401 A1
(43) Pub. Date: Oct. 18, 2018

(54) MULTI-LEVEL LEAD FRAME STRUCTURES AND METHOD OF PROVIDING SAME

(71) Applicant: Intel Corporation, Santa Clara, CA (US)

(72) Inventor: Arvind SUNDARAM, Bangalore (IN)

(21) Appl. No.: 15/486,171

(22) Filed: Apr. 12, 2017

(51) Int. Cl. H01L 23/495; H01L 21/48; H01L 23/31

(52) U.S. Cl. CPC H01L 23/49551; H01L 23/3114; H01L 21/4842; H01L 21/4821

(57) ABSTRACT

Techniques and mechanisms for providing connectivity to integrated circuitry using a lead frame. In an embodiment, the lead frame includes a conductor which forms a frame portion and a plurality of branch structures each extending from the frame portion. The frame portion is disposed in a region between a first plane and a second plane, wherein a portion of a first branch structure extends outside of the region. In another embodiment, the plurality of branch structures are coupled to integrated circuitry, and the frame portion is subsequently removed to form from the plurality of branch structures a plurality of leads. Removal of the frame portion forms a first lead from the first branch structure, wherein the first lead extends over or under one or more other structures in the region between the first plane and the second plane.

### BACKGROUND

### 1. Technical Field

Embodiments of the present invention generally relate to interconnect structures and more particularly, but not exclusively, to structures of a lead frame.

### 2. Background Art

A conventional integrated circuit (IC) package includes an outer package that encapsulates integrated circuitry such as that of an IC chip. Packaging usually includes encapsulating the IC chip in a mold material, where electrical contacts are provided on the exterior of the resulting packaged device to provide an interface to the IC chip. Usually, the packaged device is subsequently coupled to any of various external elements such as a circuit board.

Often, the dimensions and cost of circuit assemblies can be reduced, and system performance improved, if integrated circuitry can be arranged more densely over the surface of a circuit board or other such underlying support structure. In order to increase processing power and/or functionality within a given footprint, many IC packaging systems include two or more IC chips. For example, a “stacked die” IC packaging system includes an IC package with two or more IC chips stacked therein. In another example, a “stacked package” IC packaging system includes several IC packages stacked on one another, with each of the IC packages having one or more IC die therein. Stacked IC packages are usually separated by a solid polymer interposer including conductive plugs for electrically coupling adjacent IC packages with each another.

As systems with packaged IC devices continue to grow in number, variety and capability, there is expected to be an increasing premium placed on incremental improvements to the arrangement of such packaged IC devices.

### BRIEF DESCRIPTION OF THE DRAWINGS

The various embodiments of the present invention are illustrated by way of example, and not by way of limitation, in the figures of the accompanying drawings and in which:

FIG. 1 shows various perspective views of a lead frame structure according to an embodiment.

FIG. 2 is a flow diagram illustrating elements of a process to interconnect circuitry with a lead frame according to an embodiment.

FIGS. 3A-3G shows perspective views each of respective structures during a corresponding stage of a process to interconnect circuitry with a structures of a lead frame according to an embodiment.

FIG. 4 is a functional block diagram illustrating elements of a computer device according to an embodiment.

FIG. 5 is a functional block diagram illustrating elements of a computer system according to an embodiment.

### DETAILED DESCRIPTION

Embodiments discussed herein variously include techniques and/or mechanisms for providing interconnect structures using a lead frame. In an embodiment, at least one such interconnect structure is formed from a lead frame comprising a frame portion disposed between parallel planes. The at least one interconnect structure may be configured to couple to integrated circuitry, where a portion of the interconnect structure is to communicate a voltage or a signal along a line of direction which is orthogonal to, or oblique to, the parallel planes. For example, one of the parallel planes may be disposed between the other of the parallel planes and the portion of the interconnect structure.

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices including branch structures described herein.

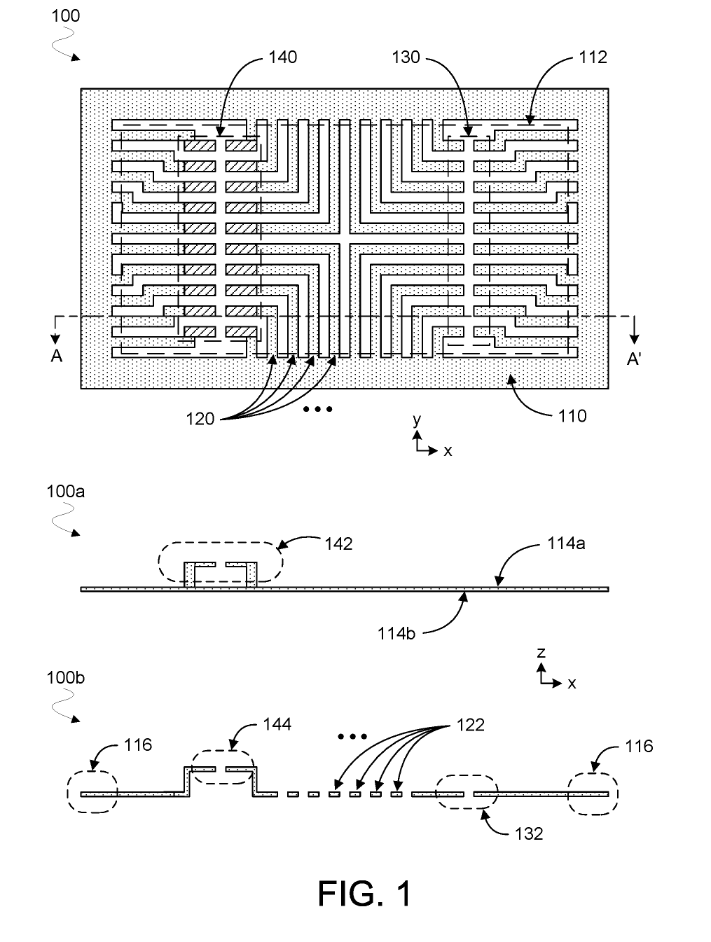

FIG. 1 shows features of a lead frame 100 to facilitate interconnection of circuit components according to an embodiment. Lead frame 100 is shown from the x-y plane elevation of a xyz coordinate system. FIG. 1 also shows a side view 100a and a cross-sectional view 100b of lead frame 100—the views 100a, 100b each from a respective x-z plane elevation of the xyz coordinate system. View 100b corresponds to a cross-section A-A′ which, as shown in FIG. 1, is perpendicular to the x-y plane.

Lead frame 100 is one example of an embodiment wherein a conductor includes a frame portion extending between a first plane and a second plane parallel to the first plane (such as the illustrative planes 114a, 114b shown edgewise in view 100a). In such an embodiment, a plurality of branch structures may each extend from the frame portion—e.g., the plurality of branch structures including a first branch structure, wherein the second plane is between the first plane and a portion of the first branch structure.

Referring now to lead frame 100, a conductive structure forms branch portions (referred to herein as “branch structures”) as well as a framework structure from which such branch portions variously extend. The framework (referred to herein as a “frame portion”) may extend along—e.g. at least partially around—a region into which some or all of the branch structures extend at least in part. In such an embodiment, one or more of the branch structures may each include a respective portion that extends above a top side (or below a bottom side) of the frame portion. In providing branch structure portions which variously extend each in a respective direction away from the x-y plane, a lead frame according to an embodiment may enable the formation of leads which are routed over or below (rather than around) one or more other structures in such an x-y plane.

In the illustrative embodiment shown, lead frame 100 includes a frame portion 110 which extends at least partially around a region 112, where branch structures 120 of the lead frame 100 variously branch from frame portion 110 (some or all of which may extend into region 112). The particular number, size and relative arrangement of branch structures 120 may vary in different embodiments—e.g., according to the particular signal lead and/or voltage lead routing requirements of a given use case.

The branch structures 120 and frame portion 110 may be formed from a sheet of conductive material (referred to herein as a “plate conductor”) which is initially disposed between parallel planes 114a, 114b. For some or all of branch structures 120, a respective section of that branch structure may form a flat top side and flat bottom side opposite the flat top side. For example, a cross-section of such a branch structure may have rectilinear (e.g., a square or other rectangular) profile—e.g., wherein the cross-section is orthogonal to a line of direction along which current is to flow in a lead formed by the branch structure.

As variously shown in views 100a, 100b, at least one of branch structures 120 may form one or more bends (e.g., including one or more curved bends and/or one or more angled bends) within a plane—such as the x-z plane shown—which is perpendicular to planes 114a, 114b. For example, multiple branch structures may each form multiple bends each in a respective plane which is perpendicular to planes 114a, 114b. Although some embodiments are not limited in this regard, one such branch structure may also may form one or more other bends in a plane (such as the x-y plane shown) which is parallel to planes 114a, 114b.

As shown in the x-y plane elevation of lead frame 100, branch structures 120 may be variously routed each along a respective path—e.g., where some portions of branch structures 120 may extend in parallel with the x-y plane shown. For example, respective portions of at least some branch structures may extend to facilitate various routing of a respective signal, voltage, etc. each in a respective direction that is parallel to the plane 114a in which extends a top side of frame portion 110.

By contrast, for at least one of branch structures 120, a portion of the branch structure may extend primarily in a direction other than one that is parallel to the x-y axis. For example, at least a section of one of branch structures 120 may primarily extend in a direction that is oblique to, or even perpendicular to, the x-y plane. In the context of such a section of a branch structure, “primarily extends” refers herein to the characteristic of the section having a longest dimension which is parallel to the plane in question—e.g., wherein a smallest cross-sectional area of the section is for a cross-section which is orthogonal to the plane.

In one illustrative embodiment, branch structures 120 include one or more portions 140 which extend to a region 142 that is above plane 114a (where plane 114a is between region 142 and plane 114b). In the example embodiment shown in view 100b, some of branch structures 120 may variously extend from frame portion 110, where distal ends 144 of such branch structures are each at a respective height (along the z-axis) other than that of frame portion 110. By contrast, other branch structure portions may extend in the same range of z-axis heights as does the frame portion 110. For example, some of branch structures 120 may each extend primarily in parallel with the x-y plane—e.g., where no portion of such branch structures extends above frame portion 110 or below frame portion 110. As shown in cross-sectional view 100b, some of branch structures 120 may include respective portions 130 that are co-planar with frame portion 110—e.g., wherein portions 130 include distal ends 132 which are at the same range of (z-axis) levels of frame portion 110.

Lead frame 100 may include copper, gold, aluminum, silver and/or any of a variety of other metals used in circuit devices. Although some embodiments are not limited in this regard, a length (x-axis dimension) of lead frame 100 may be in a range of 2 centimeters (cm) to 6 cm—e.g., wherein a width (y-axis dimension) of lead frame 100 is in a range of 2 cm to 6 cm and/or an overall thickness (z-axis dimension) of lead frame 100 may be in a range of 3 millimeters (mm) to 15 mm. Leg structures 116 of frame portion 110 (shown in cross-section by view 100b) may each have a respective length in a range of 2 mm to 30 mm. Cross-sections 122 of branch structures 120 may, for example, each have a respective height in a range of 3 mm to 15 mm. However, such lead frame dimensions are merely illustrative, and may vary in different embodiments according to implementation-specific details.

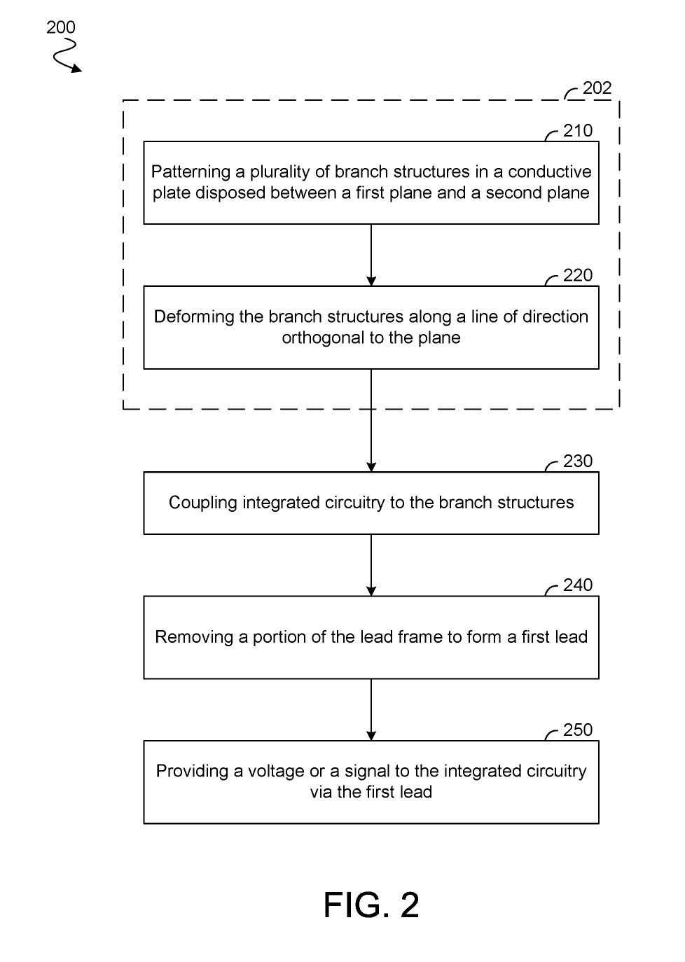

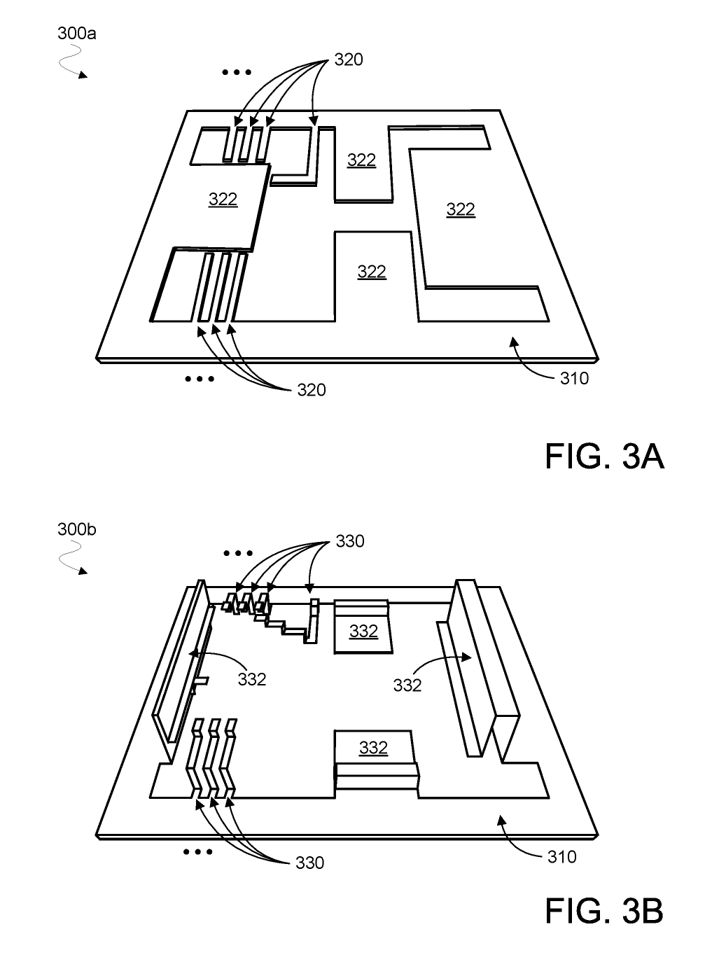

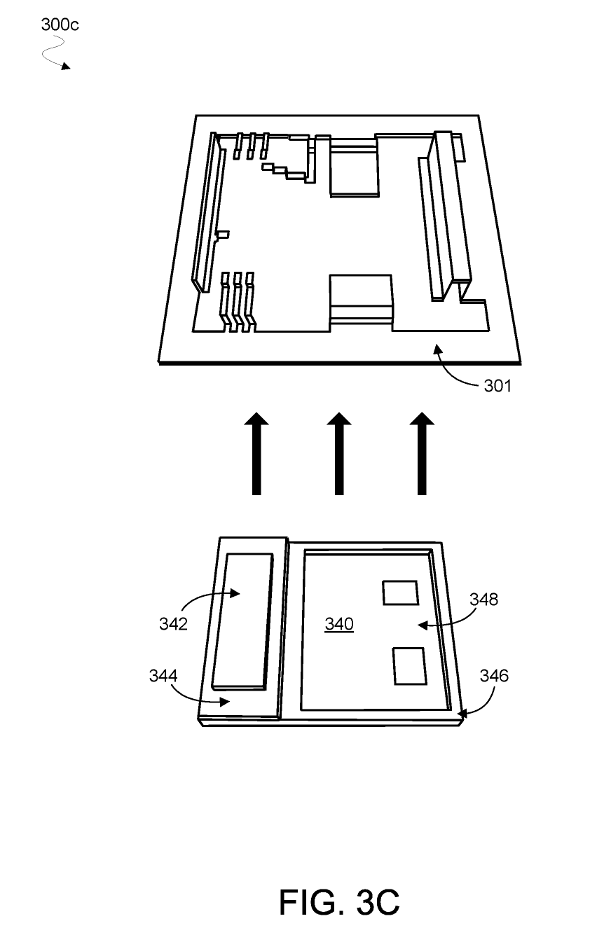

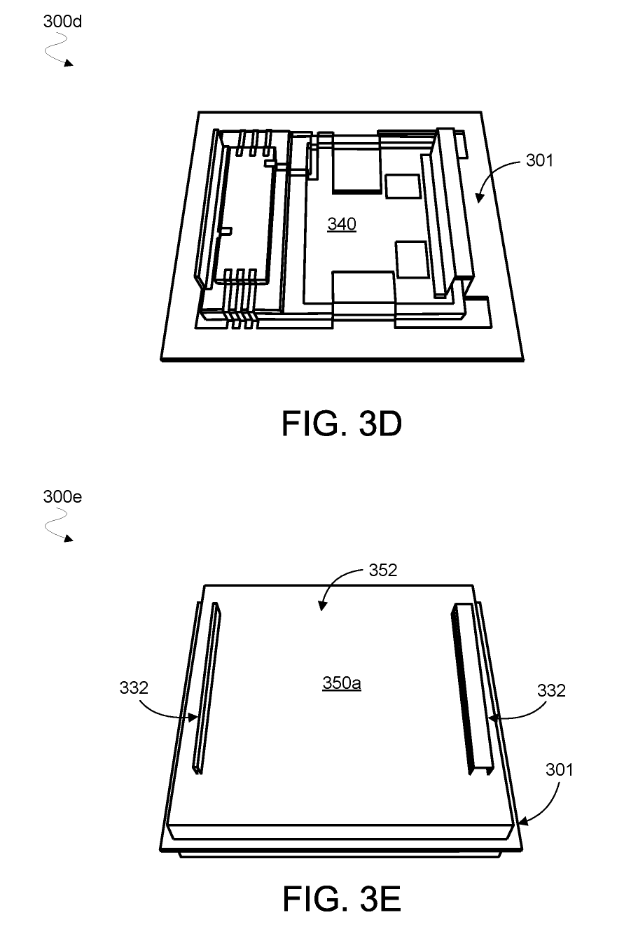

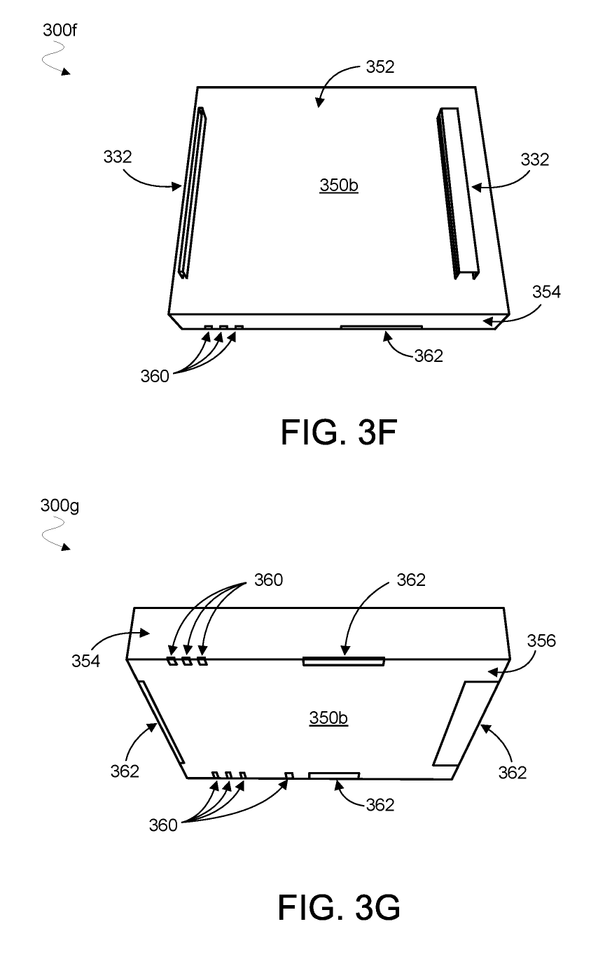

FIG. 2 shows features of a method 200 to provide interconnect structures with a lead frame according to an embodiment. Method 200 may be performed to fabricate lead frame 100, for example. FIGS. 3A-3G show respective stages 300a-300g of processing to fabricate, according to an embodiment, interconnect structures using a lead frame such as lead frame 100. To illustrate certain features of various embodiments, method 200 is described herein with respect to processing to fabricate structures such as those shown in stages 300a-300g. However, such description may be extended to apply to any of processing which fabricates any of a variety of additional or alternative interconnect structures having features described herein.

Method 200 may include operations 202 to fabricate a lead frame such as that resulting from processing which includes stages 300a, 300b. In an embodiment, operations 202 include, at 210, patterning a plurality of branch structures in a conductive plate, wherein a surface of the conductive plate is disposed between a first plane and a second plane parallel to the first plane. Referring now to FIG. 3A, a plate conductor may be plated, stamped, cut, etched or otherwise formed (at stage 300a) to include a frame portion 310 and branch structures (such as the illustrative branch structures 320, 322) which variously extend from frame portion 310. The particular number, sizes and configuration of branch structures 320, 322 at stage 300a is merely illustrative, and not limiting on some embodiments.

Operations 202 may further comprise, at 220, deforming a first branch structure of the plurality of branch structures, wherein after the deforming, the second plane is between the first plane and a portion of the first branch structure. The deforming at 220 may include deforming some or all of the plurality of branch structures each to form a respective one or more bend structures as variously described herein. The first branch structure may, for example, be deformed along a line of direction which is orthogonal to (or oblique to) the first plane. As shown in FIG. 3B, one or more branch structures extending from frame portion 310 may each be variously stamped or otherwise deformed (at stage 300b) to extend from—e.g., extend above and/or extend below—a respective plane in which a side of frame portion 310 extends.

After the deforming at 220, the first branch structure may extend outside of a region between the first plane and the second plane—e.g., to a height which is multiple times a height of the first branch structure between the first plane and the second plane. By way of illustration and not limitation, an overall height of the first branch structure may be more than three times—and in an embodiment, more than five times—a smallest z-axis height of any cross-section (also referred to herein as a “smallest cross-sectional height”) of the first branch structure.

In an embodiment, the first branch structure forms a bend in a plane which is perpendicular to one of the first plane and the second plane (e.g., a plane which is perpendicular to planes 114a, 114b). For example, the first branch structure may form multiple bends (e.g., including one or more angled bends and/or curved bends) each in a respective plane which is perpendicular to the first plane. The first branch structure may further form one or more bends each in a respective plane which is parallel to one of the first plane and the second plane. One or more bends of the first branch structure may form any of a variety of structures which extend at least in part outside of the first plane and the second plane. Such structures may include, for example, a U-shaped structure and/or multiple portions arranged in a stepped configuration with each other.

In some embodiments, method 200 may additionally or alternatively include operations to form from a lead frame (such as that formed by operations 202) leads which interconnect circuit components. For example, method 200 may include, at 230, coupling integrated circuitry to the branch structures. Referring now to stage 300c of FIG. 3C, a three-dimensional lead frame 301—resulting from the processing variously illustrated by stages 300a, 300b—may be assembled with other circuit structures that, for example, are variously disposed in or on a circuit board 340. For example, some or all of branch structures 330, 332 may be variously soldered or otherwise electrically coupled each to a corresponding conductive contact of circuit board 340 or a corresponding conductive contact of a circuit component disposed on circuit board 340. Such components may form various surfaces (e.g., including the illustrative surfaces 342, 344, 346, 348 shown) having different respective z-height levels. The particular number, sizes, height and/or other configuration of the multi-level surfaces 342, 344, 346, 348 is merely illustrative, and may vary in different embodiments according to implementation-specific details. The resulting assembly of lead frame 301 and circuit board 340 (and, in some embodiments, components disposed on circuit board 340) is shown at stage 300d of FIG. 3D.

Method 200 may further comprise, at 240, removing a portion of the lead frame to form a first lead. For example, a packaged device 350a (at stage 300e shown in FIG. 3E) may be formed by disposing a mold material on—e.g., around—at least a portion of the assembly shown in FIG. 3D. Although some embodiments are not limited in this regard, one or more structures of the lead frame 301 may extend from the package material of packaged device 350a. For example, some or all of frame portion 310 may extend from one or more side surfaces of the packaged material—e.g., wherein portions of branch structures 332 extend from a top surface 352 of the package material.

As shown at stage 300f of FIG. 3F, portions of the packaged device 350a may be selectively cut, ground or otherwise removed—e.g., at 240 of method 200—to form a smaller packaged device 350b. In the illustrative embodiment shown, such removal may variously form leads each from a respective one of branch structures 330, 332. By way of illustration and not limitation, dicing and/or other cutting of packaged device 350a may expose a sidewall 354 of packaged device 350b, including end portions 360 of leads each formed from a respective one of branch structures 330. Alternatively or in addition, such dicing and/or other cutting may expose end portions 362 of leads variously formed each from a respective one of branch structures 332. At the illustrative stage 300g shown in FIG. 3G, a bottom surface 356 of packaged device 350b—e.g., the bottom surface 356 opposite top surface 352—may have therein respective portions of one or more leads (such as the illustrative end portions 360, 362 shown).

The resulting packaged device 350b formed at stage 300g may include a package mold forming a sidewall 354 which extends around a periphery of packaged device 350b. The packaged device 350b may further comprise integrated circuitry disposed in the package mold, wherein a plurality of leads are each coupled to a respective conductive contact of the integrated circuitry. Respective distal ends of the plurality of leads—e.g., including end portions 360, 362 shown—may each extend to the sidewall 354 in a region which is between a first plane and a second plane (e.g., a region between planes 114a, 114b). In such an embodiment, other respective portions of one or more such leads may extend outside of the region between the first plane and the second plane. Although some embodiments are not limited in this regard, the respective distal ends of the plurality of leads may each have the same surface texture—e.g., wherein the surface texture is a residual artifact of cutting, grinding, polishing and/or other processing to separate the leads from the frame portion of the lead frame. Such a surface texturing may also be present at adjoining regions of sidewall 354, for example. In some embodiments, the plurality of leads each have the same smallest cross-sectional (z-axis) height—e.g., wherein cross-sections of the plurality of leads each have a respective rectilinear shape.

Method 200 may additionally or alternatively include operating circuit components which are interconnected via leads having features of those formed from a lead frame fabricated by operations 202. For example, method 200 may include, at 250, providing a voltage or a signal to the integrated circuitry via the first lead (and in some embodiments, providing other voltages and/or signals to the integrated circuitry via other such leads).

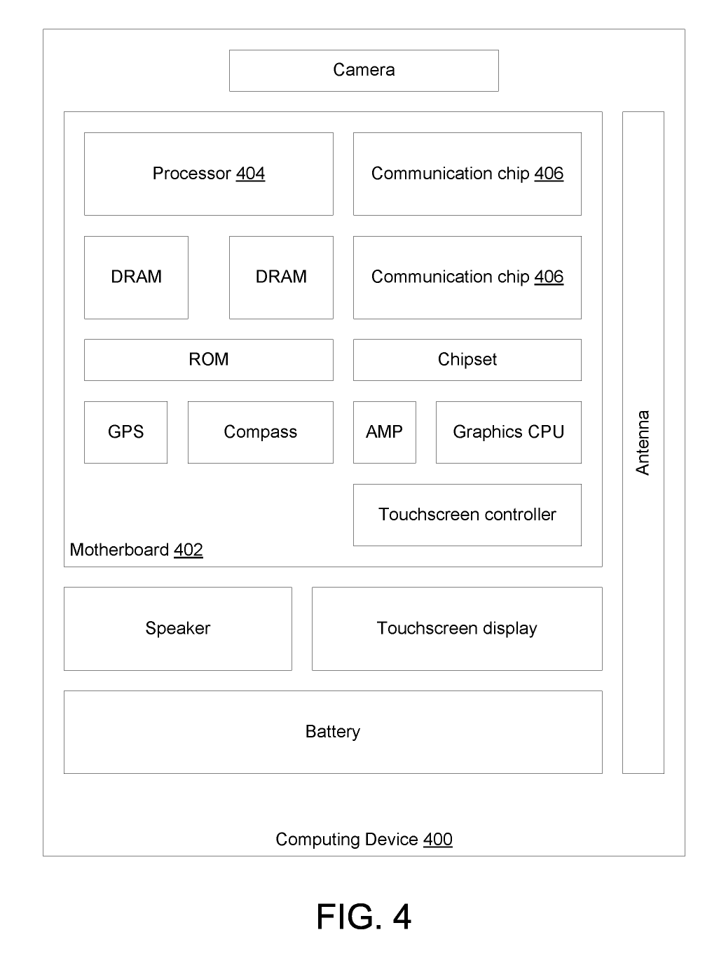

FIG. 4 illustrates a computing device 400 in accordance with one embodiment. The computing device 400 houses a board 402. The board 402 may include a number of components, including but not limited to a processor 404 and at least one communication chip 406. The processor 404 is physically and electrically coupled to the board 402. In some implementations the at least one communication chip 406 is also physically and electrically coupled to the board 402. In further implementations, the communication chip 406 is part of the processor 404.

Depending on its applications, computing device 400 may include other components that may or may not be physically and electrically coupled to the board 402. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 406 enables wireless communications for the transfer of data to and from the computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 406 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, Ev-DO, and others.

The processor 404 of the computing device 400 includes an integrated circuit die packaged within the processor 404. The term “processor” may refer to any device or portion of a device that processes electronic data from registers and/or memory to transform that electronic data into other electronic data that may be stored in registers and/or memory. The communication chip 406 also includes an integrated circuit die packaged within the communication chip 406.

In various implementations, the computing device 400 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 400 may be any other electronic device that processes data.

Some embodiments may be provided as a computer program product, or software, that may include a machine-readable medium having stored thereon instructions, which may be used to program a computer system (or other electronic devices) to perform a process according to an embodiment. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

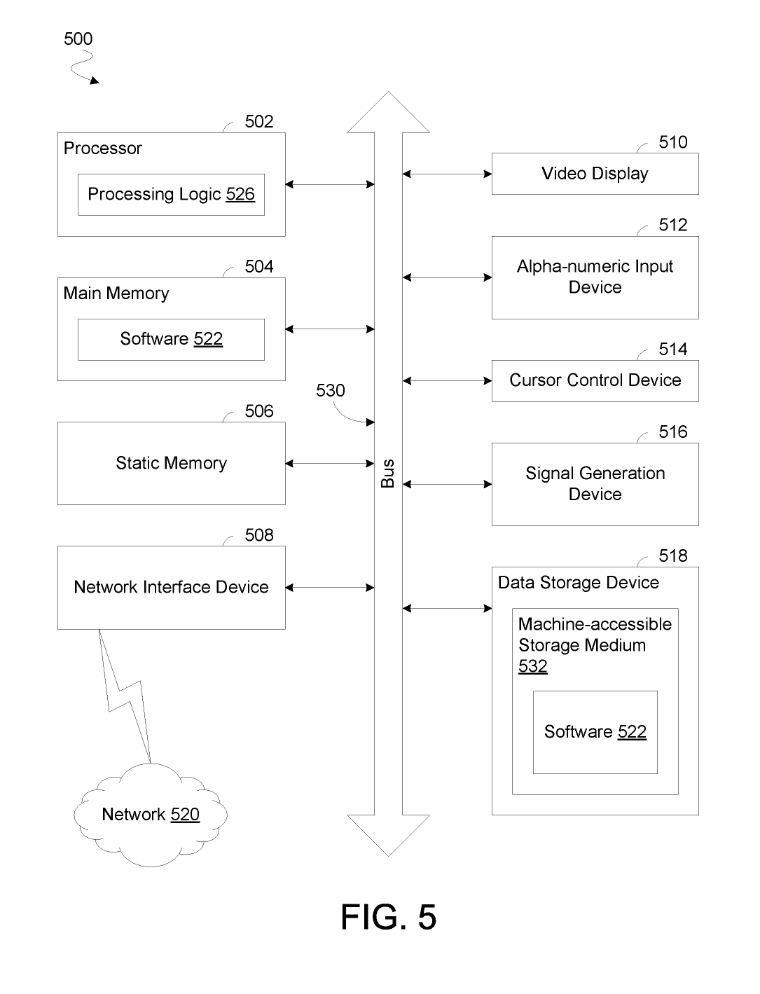

FIG. 5 illustrates a diagrammatic representation of a machine in the exemplary form of a computer system 500 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 500 includes a processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a secondary memory 518 (e.g., a data storage device), which communicate with each other via a bus 530.

Processor 502 represents one or more general-purpose processing devices such as a microprocessor, central processing unit, or the like. More particularly, the processor 502 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 502 may also be one or more special-purpose processing devices such as an application specific integrated circuit (ASIC), a field programmable gate array (FPGA), a digital signal processor (DSP), network processor, or the like. Processor 502 is configured to execute the processing logic 526 for performing the operations described herein.

The computer system 500 may further include a network interface device 508. The computer system 500 also may include a video display unit 510 (e.g., a liquid crystal display (LCD), a light emitting diode display (LED), or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium (or more specifically a computer-readable storage medium) 532 on which is stored one or more sets of instructions (e.g., software 522) embodying any one or more of the methodologies or functions described herein. The software 522 may also reside, completely or at least partially, within the main memory 504 and/or within the processor 502 during execution thereof by the computer system 500, the main memory 504 and the processor 502 also constituting machine-readable storage media. The software 522 may further be transmitted or received over a network 520 via the network interface device 508.

While the machine-accessible storage medium 532 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any of one or more embodiments. The term “machine-readable storage medium” shall accordingly be taken to include, but not be limited to, solid-state memories, and optical and magnetic media.

In one implementation, a lead frame comprises a conductor including a frame portion disposed between a first plane and a second plane parallel to the first plane, and a plurality of branch structures each extending from the frame portion, the plurality of branch structures including a first branch structure, wherein the second plane is between the first plane and a portion of the first branch structure.

In one embodiment, the first branch structure forms a bend in a plane which is perpendicular to the first plane. In another embodiment, the first branch structure forms multiple bends each in a respective plane which is perpendicular to the first plane. In another embodiment, the first branch structure forms one or more bends each in a respective plane which is parallel to the first plane. In another embodiment, the first branch structure forms a U-shaped structure. In another embodiment, the first branch structure includes multiple portions arranged in a stepped configuration with each other. In another embodiment, an overall height of the first branch structure is more than three times a smallest cross-sectional height of the first branch structure. In another embodiment, the overall height of the first branch structure is more than five times the smallest cross-sectional height of the first branch structure.

In another implementation, a method comprises patterning a plurality of branch structures in a conductive plate disposed between a first plane and a second plane parallel to the first plane, and deforming a first branch structure of the plurality of branch structures along a line of direction orthogonal to the first plane, wherein after the deforming, the second plane is between the first plane and a portion of the first branch structure. The method further comprises coupling integrated circuitry to the branch structures, and after the interconnecting, removing a portion of the lead frame to form a first lead.

In one embodiment, the first branch structure forms a bend in a plane which is perpendicular to the first plane. In another embodiment, the first branch structure forms multiple bends each in a respective plane which is perpendicular to the first plane. In another embodiment, the first branch structure forms one or more bends each in a respective plane which is parallel to the first plane. In another embodiment, the first branch structure forms a U-shaped structure. In another embodiment, the first branch structure includes multiple portions arranged in a stepped configuration with each other. In another embodiment, an overall height of the first branch structure is more than three times a smallest cross-sectional height of the first branch structure. In another embodiment, the overall height of the first branch structure is more than five times the smallest cross-sectional height of the first branch structure. In another embodiment, removing the portion of the lead frame forms multiple leads including the first lead, the method further comprising depositing a package material around the integrated circuitry and the multiple leads. In another embodiment, the method further comprises providing a voltage or a signal to the integrated circuitry via the first lead.

In another implementation, a packaged device comprises a package mold forming a sidewall which extends around a periphery of the packaged device, integrated circuitry disposed in the package mold, and a plurality of leads each coupled to a respective conductive contact of the integrated circuitry, wherein respective distal ends of the plurality of leads each extend to a region of the sidewall between a first plane and a second plane parallel to the first plane, wherein the second plane is between the first plane and a portion of the first branch structure.

In one embodiment, the first lead forms a bend in a plane which is perpendicular to the first plane. In another embodiment, the first lead forms multiple bends each in a respective plane which is perpendicular to the first plane. In another embodiment, the first lead forms one or more bends each in a respective plane which is parallel to the first plane. In another embodiment, the first lead forms a U-shaped structure. In another embodiment, the first lead includes multiple portions arranged in a stepped configuration with each other. In another embodiment, an overall height of the first lead is more than three times a smallest cross-sectional height of the first lead. In another embodiment, the overall height of the first lead is more than five times the smallest cross-sectional height of the first lead.

Techniques and architectures for providing structures to interconnect circuitry are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

1. A lead frame comprising:
a conductor including:
a frame portion disposed between a first plane and a second plane parallel to the first plane, the frame portion having a continuous outer portion; and
a plurality of branch structures each extending from the continuous outer portion of the frame portion, the plurality of branch structures including a first branch structure, wherein the second plane is between the first plane and a portion of the first branch structure, and wherein the first branch structure forms a bend in a plane which is perpendicular to the first plane.

2. (canceled)

3. The lead frame of claim 1, wherein the first branch structure forms multiple bends each in a respective plane which is perpendicular to the first plane.

4. The lead frame of claim 1, wherein the first branch structure forms one or more bends each in a respective plane which is parallel to the first plane.

5. The lead frame of claim 1, wherein the first branch structure forms a U-shaped structure.

6. The lead frame of claim 1, wherein the first branch structure includes multiple portions arranged in a stepped configuration with each other.

7. The lead frame of claim 1, wherein an overall height of the first branch structure is more than three times a smallest cross-sectional height of the first branch structure.

8. The lead frame of claim 7, wherein the overall height of the first branch structure is more than five times the smallest cross-sectional height of the first branch structure.

9. A method comprising:
patterning a plurality of branch structures in a conductive plate disposed between a first plane and a second plane parallel to the first plane;
deforming a first branch structure of the plurality of branch structures along a line of direction orthogonal to the first plane, wherein after the deforming, the second plane is between the first plane and a portion of the first branch structure;
coupling integrated circuitry to the branch structures; and
after the interconnecting, removing a portion of the lead frame to form a first lead.

10. The method of claim 9, wherein the first branch structure forms a bend in a plane which is perpendicular to the first plane.

11. The method of claim 9, wherein the first branch structure forms a U-shaped structure.

12. The method of claim 9, wherein the first branch structure includes multiple portions arranged in a stepped configuration with each other.

13. The method of claim 9, wherein an overall height of the first branch structure is more than three times a smallest cross-sectional height of the first branch structure.

14. The method of claim 9, wherein removing the portion of the lead frame forms multiple leads including the first lead, the method further comprising depositing a package material around the integrated circuitry and the multiple leads.

15. The method of claim 9, further comprising providing a voltage or a signal to the integrated circuitry via the first lead.

16. A packaged device comprising:
a package mold forming a sidewall which extends around a periphery of the packaged device;
integrated circuitry disposed in the package mold;
a plurality of leads each coupled to a respective conductive contact of the integrated circuitry, wherein respective distal ends of the plurality of leads each extend to a region of the sidewall between a first plane and a second plane parallel to the first plane, wherein the second plane is between the first plane and a portion of the first branch structure.

17. The packaged device of claim 16, wherein the first lead forms a bend in a plane which is perpendicular to the first plane.

18. The packaged device of claim 16, wherein the first lead forms a U-shaped structure.

19. The packaged device of claim 16, wherein the first lead includes multiple portions arranged in a stepped configuration with each other.

20. The packaged device of claim 16, wherein an overall height of the first lead is more than three times a smallest cross-sectional height of the first lead.
